(19) United States
(12) Patent Application Publication
(10) Pub. No.: US 2022/0167522 A1
(43) Pub. Date: May 26, 2022

(54) PRE-CABLED DRAWER SYSTEM FOR COMPUTER NETWORKING EQUIPMENT

(71) Applicant: Rich Slodkowski, Shorewood, IL (US)

(72) Inventor: Rich Slodkowski, Shorewood, IL (US)

(21) Appl. No.: 17/447,134

(22) Filed: Sep. 8, 2021

Related U.S. Application Data
(60) Provisional application No. 63/198,970, filed on Nov. 25, 2020.

(51) Int. Cl. H05K 7/14

(52) U.S. Cl. CPC H05K 7/1489; H05K 7/183; H05K 7/1447

(57) ABSTRACT

A drawer type installation for computer equipment within a computer infrastructure environment. A chassis is configured to contain computer equipment that is pre-cabled and coupled with a first connector. The chassis adapted to insert into a rack with a receiver chassis. The first connector operatively couples with a second connector that is connected with a second wiring to the computer infrastructure environment.

### CROSS-REFERENCE TO RELATED APPLICATION

This application claims the benefit of priority of U.S. provisional application No. 63/198,970 filed Nov. 25, 2020, the contents of which are herein incorporated by reference.

### BACKGROUND OF THE INVENTION

The present invention relates to computer networking equipment and, more particularly, to a pre-cabled drawer system for computer networking equipment.

It takes a large amount of time to replace or install network equipment. Further, sometimes technical individuals are not available to perform such a task. When equipment breaks, it becomes necessary to schedule a trained professional for installation and repair, or someone onsite must perform the un-cabling to uninstall and the cabling to re-install. The potential to incorrectly re-wire and complicate things during emergency repair is great.

Businesses suffer in the face of hardware failure as they grow, some globally, and the need for support personnel becomes greater.

As can be seen, there is a need for a solution to one or more of these problems.

### SUMMARY OF THE INVENTION

In one aspect of the present invention, a pre-cabled drawer system for operatively connecting a hardware component with a computing infrastructure is disclosed. The pre-cabled drawer system includes a removable chassis is configured as a tray to contain the hardware component. A first connector is mounted to an aft wall of the removable chassis. A first wiring operatively connects the hardware component with the first connector. A rack configured to receive the removable chassis therein. A second connector is attached with an aft end of the rack with a second wiring operatively connecting the second connector with the computing infrastructure. The first connector and the second connector are cooperatively connected when the removable chassis is received within the rack.

In some embodiments, a slide element is disposed between a sidewall of the removable chassis and the rack to movably carry the chassis in the rack.

In some embodiments, the first connector and the second connector have a unique conductor configuration associated with a specified hardware package within the computing infrastructure.

In some embodiments, the first connector and the second connector have a unique cooperative body connection associated with a specified hardware package within the computing infrastructure.

In some embodiments, the first connector and the second connector have a unique position on each of the respective chassis and the rack, such that a specifically configured chassis may only be received for interconnection with the computing infrastructure at a specified location within the rack.

In some embodiments, a plurality of first connectors are disposed in a spaced apart relation about the aft wall of the removable chassis. A plurality of first wires interconnect the hardware component with the plurality of first connectors. A plurality of second connectors are attached with the aft end of the rack. The plurality of second connectors disposed in a corresponding spaced apart relation with the plurality of first connectors.

In some embodiments, a second removable chassis is configured to contain a second hardware component as a modular replacement for the hardware component of the removable chassis.

In other aspects of the invention, a drawer for operatively connecting a hardware component with a computing infrastructure is disclosed. The drawer includes a removable chassis configured as a tray to contain the hardware component. A first wiring operatively connects the hardware component with a first connector. The first connector is mounted to an aft wall of the chassis and is configured for operative connection with a second connector of a rack to receive the removable chassis therein for connection with the computing infrastructure.

In some embodiments, a power supply is contained within the removable chassis. A power conductor is operatively connected with the hardware component.

In other embodiments, a plurality of first connectors are disposed in a spaced apart relation about the aft wall of the chassis. A plurality of first wires interconnect the hardware component with the plurality of first connectors. The plurality of first connectors configured for operative connection with a plurality of second connectors attached with an aft end of the rack disposed in a corresponding spaced apart relation with the plurality of first connectors.

These and other features, aspects and advantages of the present invention will become better understood with reference to the following drawings, description and claims.

### BRIEF DESCRIPTION OF THE DRAWINGS

FIG. 1 is a perspective view of the invention with drawer open.

FIG. 2 is a perspective view of the second chassis.

FIG. 3 is a cross section view of the invention in use.

FIG. 4 is a cross section view taken along line 4-4 of FIG. 1.

FIG. 5 is a cross section view of the invention is use in a second configuration.

FIG. 6 is a cross section view of the invention is use in a second configuration.

### DETAILED DESCRIPTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

Broadly, an embodiment of the present invention provides a drawer type install for computer networking equipment. In accordance with a system of the present invention, computer equipment may be pre-cabled and adapted to insert into receiver chassis or pre-installed in the pre-cabled drawer for computer networking equipment.

The present invention may include at least one computer with a user interface. The computer may include at least one processing unit coupled to a form of memory. The computer may include, but not limited to, a microprocessor, a server, a desktop, laptop, and smart device, such as, a tablet and smart phone. The computer includes a program product including a machine-readable program code for causing, when executed, the computer to perform steps. The program product may include software which may either be loaded onto the computer or accessed by the computer. The loaded software may include an application on a smart device. The software may be accessed by the computer using a web browser. The computer may access the software via the web browser using the internet, extranet, intranet, host server, internet cloud and the like.

The ordered combination of various ad hoc and automated tasks in the presently disclosed platform necessarily achieve technological improvements through the specific processes described more in detail below. In addition, the unconventional and unique aspects of these specific automation processes represent a sharp contrast to merely providing a well-known or routine environment for performing a manual or mental task.

As shown at FIGS. 1-4, in an exemplary embodiment, the present invention may include a pre-cabled drawer for computer networking equipment. In one aspect, the pre-cabled drawer may be a drawer-like container for computer networking equipment to be installed and pre-cabled to a connector to allow for quick install and removal and/or replacement into a housing network rack.

The present invention may not only reduce the amount of time to replace or install network equipment but may eliminate the need for technical support personnel to perform the task. When equipment breaks, it may no longer be necessary to schedule a trained professional for onsite un-cabling or cabling reinstall. The present invention further reduces the likelihood that someone may incorrectly re-wire and complicate things during an emergency repair. The present invention may lessen the need for businesses to hire support personnel in the event of hardware failure. Site managers, administrators or even business owners may take advantage of the pre-cabled-to-connector design of the present invention which may enable replacement of hardware, and removing and replacing equipment, to become as easy as opening and closing a drawer. Failed equipment or even upgrades may be swapped in seconds by almost anyone.

As stated above, the amount of time to replace or install network equipment and the need for technical support personnel to perform the task may be reduced by the present invention. Tech support may no longer be needed to perform any necessary un-cabling/cabling and reinstall. The potential to incorrectly re-wire and complicate things during emergency repair may be reduced or eliminated by use of the present invention.

The pre-cabled drawer install design of the present invention may not require an IT professional/technician to install or replace. In one aspect, the present invention may comprise a pre-cabled drawer or adaptor. In a further aspect, the present invention may comprise the pre-cabled drawer/receiver chassis of the present invention, and pre-installed computer hardware including pre-installed software, all provided as a “standby spare” ready to replace hardware in need of repair or replacement. Remote management from a central location may become easier. There may be no need for scheduling a technician and waiting, and there may be less downtime. Anyone may install or replace computer networking equipment as it may be as simple as opening and closing a kitchen drawer, or exchanging the drawer for a substantially identical new or spare drawer or adapted hardware. The pre-cabled to connector design allows for quick install/swap by almost anyone. Having a standby chassis pre-cabled during non-emergency operation may be easily swapped in a matter of seconds vs. potentially an hour or more without the present invention. Having a standby chassis pre-cabled and pre-equipped with replacement hardware during non-emergency operation may easily also be easily swapped in a matter of seconds vs. potentially an hour or more for comparable technical support and equipment installation, without the present invention.

The present invention distinguishes over and differs from what currently exists. The need to have technical support personnel to replace equipment is mitigated. Also, no need for technicians to have to revisit once installed. The present invention provides ease of installation.

Some equipment may have up to 50 cables, and in order to replace equipment those cables have to be removed, moved out of the way, and the equipment must be removed. The reverse process must later be followed to install any replacement equipment. In some cases support needs to be scheduled, which may cause business continuity impact. In use, the system of the present invention provides a system and method for replacing failed equipment, or even installing upgrades to equipment, pre-installed in a pre-cabled, drawer or adapted to slide into a chassis which may be swapped in seconds by almost anyone.

In an exemplary embodiment, the present invention may also provide an Intelligent management system (Artificial intelligence), which may be used as Admin-in-a-Box™.

FIG. 1 is a perspective view of an exemplary embodiment of the present invention. As seen at FIG. 1, the system may comprise a drawer 10 which has an exterior portion, an interior portion, a front portion, a rear portion, a first side portion, and a second side portion. The drawer 10 comprises a chassis assembly 12. The drawer 10 is constructed and arranged to be large enough to accept and accommodate hardware to be installed or replaced. The chassis assembly 12 comprises a first chassis portion 12a constructed and arranged to slide into the second chassis portion or hardware adapted itself to slide into chassis. 12b.

In some embodiments, handles 12c are located on a front exterior portion of the first chassis portion 12a. The drawer 10 is installed in any suitable computer networking rack. In accordance with the present invention, a custom networking rack 14 may comprise rack frame members 14a. Second chassis 12b may be attached to rack frame members 14a by any suitable attachment means. Suitable attachment means may comprise screws or nut and bolt assemblies, any suitable adhesive or welding or soldering. Second chassis 12b may also be integrally molded or fabricated with rack frame members 14a.

In some embodiments, the first chassis 12a may further comprise a lid (not shown) constructed and arranged to removably fit onto the first chassis and provide an enclosure. The first chassis 12a may be provided with or without a lid. The lid may be large enough to cover the hardware and equipment to be installed or replaced.

The drawer 10 may further comprise exterior slides provided on the first chassis constructed and arranged to cooperate with interior rails provided in the second chassis. In some embodiments rails/slides elements 12d comprise rails located at the interior side walls of the second chassis portion 12b, which are constructed and arranged to operatively connect with slides located on the exterior side walls of first chassis portion 12a so that in use, first chassis 12a may be slidably and removably inserted into second chassis portion 12b and supported therein.

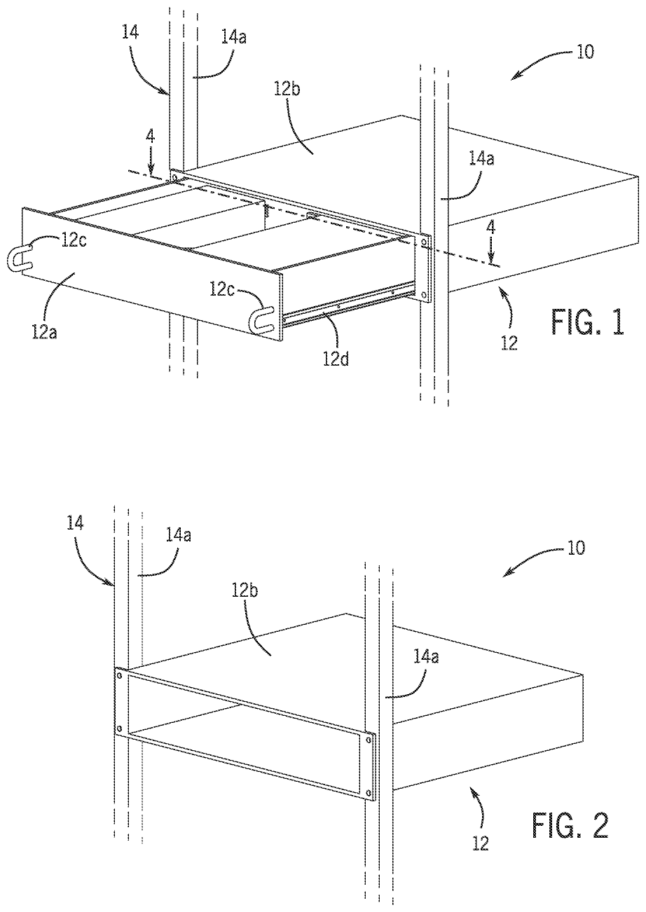

FIG. 2 shows an exemplary embodiment of drawer 10 with second chassis portion 12b constructed and arranged with no slides to accommodate larger equipment adapted with pre-cabled design and no rails

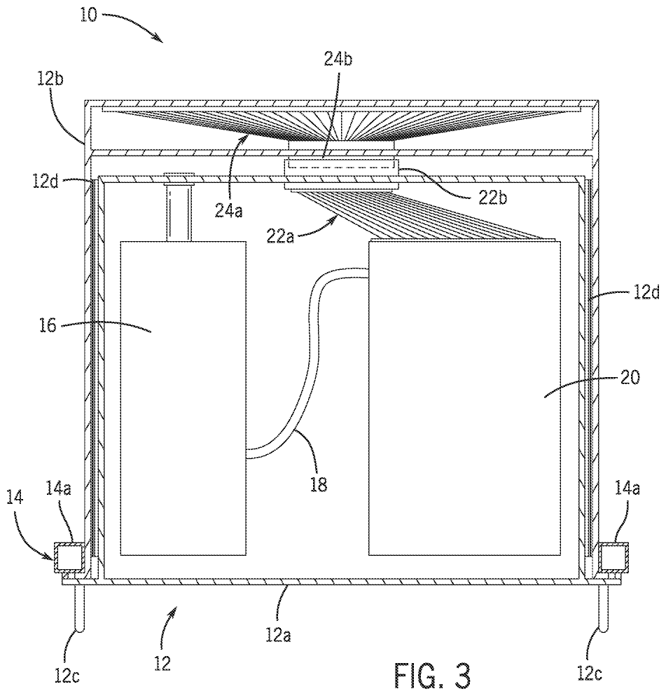

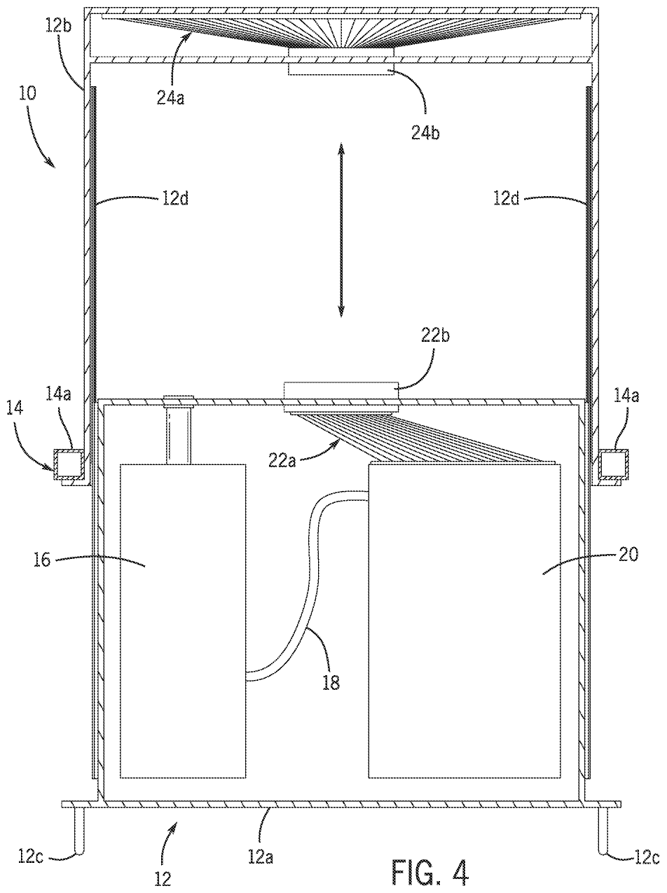

FIG. 3 is a cross-section view of an exemplary embodiment of the invention in use, showing the drawer 10 from the top. FIG. 4 shows a cross-section taken along line 4-4 of FIG. 1, showing the drawer 10 open, with first chassis 12a slidably moved relative to and exterior of second chassis 12b.

As best seen at FIGS. 3 and 4, the system may further comprise a power converter 16 located in first chassis 12a, operably connected to a power cable 18. As seen at FIGS. 3 and 4, hardware 20 may be installed in the drawer 12. Nonlimiting examples of hardware may include router, switch, wireless controller, computing device, or the like. The system may also include a first wiring adapter 22a; a first mating connector 22b, a second wiring adapter 24a and a second mating connector 24b as further described herein.

In an exemplary embodiment, the present invention may comprise one or more of the following elements or components, and combinations thereof.

1. a drawer 10 comprising a rectangular or square container (also referred to as a housing, an enclosure, a case or a chassis). The drawer 10 is constructed and arranged to be large enough to accept the respective hardware to be installed or replaced. In some embodiments, the drawer 10 may further comprise a lid constructed and arranged to removably fit onto the drawer 10 and provide an enclosure. The drawer 10 may be provided with or without a lid. The lid may be large enough to cover the respective hardware 20 to be installed or replaced. The drawer 10 may further comprise sliding rails 12d constructed and arranged for installation of the drawer 10 in any suitable fixture. Hardware 20 which may be installed in the drawer 10 or adapted. The hardware 20 may include devices such as, for example without limitation, router, switch, wireless controller, computing device, or the like.
2. at least one network cable. (802.3 Ethernet standard or fiber optic)
3. at least one unique pre-cabled connector 22a.
4. a rack or frame 14 constructed and arranged to accept a drawer-chassis 12.
5. one or more wiring connectors, such as, for example without limitation, RJ-45 connectors.

All components may be made of any suitable materials, by any suitable fabrication method.

In an exemplary embodiment, the elements or components may be interrelated in the following manner.

The drawer housing 10 (which may also be referred to as container enclosure, case or chassis) is constructed and arranged to house the equipment to be installed.

The pre-cabled connector may comprise a first end 22b and a second end 24b, having any suitable cooperating connector located at one of said first 22b or second ends 24b. First wiring 22a operatively connects the hardware 20 with the first connector 22b. Second wiring 24a operatively connects the second connector 24b with a computing infrastructure. Preferably, the first connector 22b and the second connector 24b have a unique conductor configuration and/or cooperative body connection associated with a specified hardware package 20 within the computing infrastructure. Alternatively, or in addition, the first connector 22b and the second connector 24b may have a unique position on each of the respective chassis 12 and rack 14 such that a specifically configured chassis 12 may only be received for interconnection with the computing infrastructure at a specified location within the rack 14 to receive the hardware 20 fitted within the chassis 12. The first connector 22b and the second connector 24 are thereby configured for interconnection of the hardware 20 with the computing environment by a closure of the chassis 12 within the rack 14.

In an exemplary embodiment, the drawer style install design for networking equipment in accordance with the present invention may operate in the following manner. The networking hardware piece 20 installs inside a chassis 12 and is prewired to a first connector 22a or is adapted to slide in chassis 12 as pre-cabled. The chassis 12 slides into the rack housing 14 and a mating connector 24a is on the other end that is also prewired allowing for at least one of a drawer-like installation, removal, replacement, upgrade or combinations thereof.

In an exemplary embodiment, the networking piece of equipment to be installed may or may not be housed within a chassis 12 constructed and arranged or adapted to provide the equipment pre-cabled to a connector 22a. The chassis/hardware adapted may be slidably mounted into a slot that comprises a mating connector 24a at an interior end thereof to provide and allow one or more of a drawer-like installation, removal, replacement, upgrade or combinations thereof.

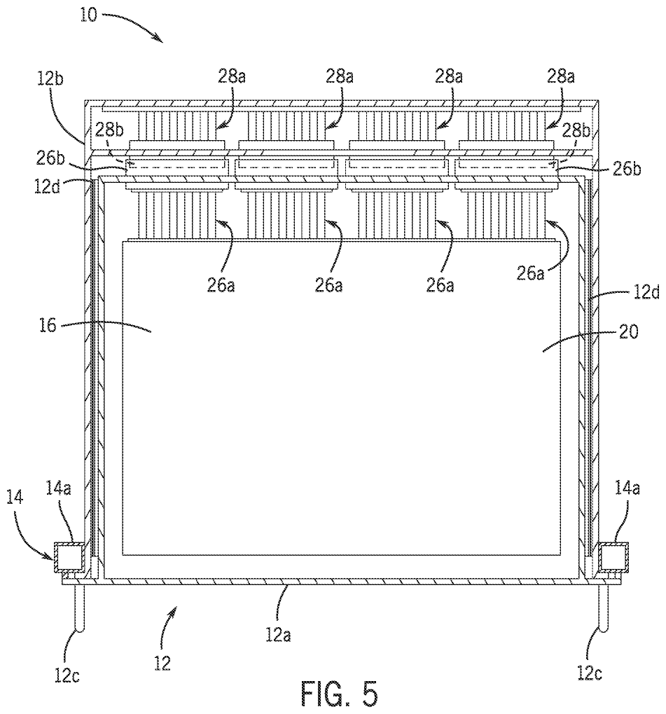

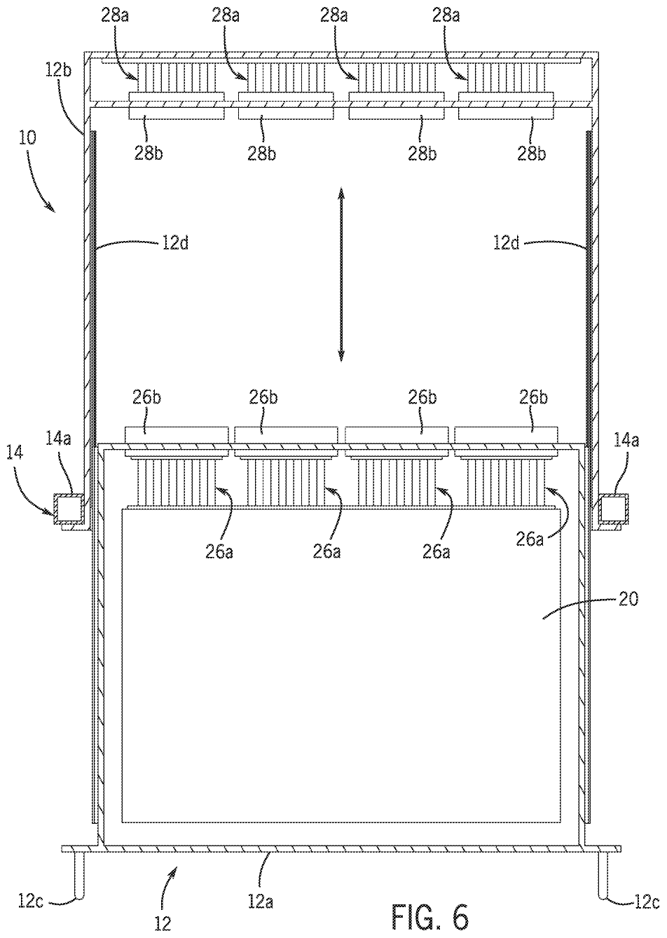

In some embodiments, such as shown in FIGS. 5 and 7, a plurality of first connectors 26b are operatively connected to one or more hardware components 20 via first wiring 26a. Likewise, a plurality of second connectors 28b are provided within the rack 14 and second wiring 28a operatively connects the second connectors 28b with the computing infrastructure. As will be appreciated different types of connectors 26b, 28b may be provided to allow slide in/out design.

In an exemplary embodiment, the present invention may be used in a process or method comprising one or more of the following steps and combinations thereof:

Provide a system in accordance with the present invention as described herein comprising a rack having at least one slot, may have a drawer 10 comprising a housing or chassis 12 and a lid, the at least one drawer 10 being constructed and arranged to be slidably mounted in the at least one slot of the rack 14; and hardware 20 adapted to slide directly in the rack 14.

Install at least one item of networking hardware equipment 20 to be deployed and secure the at least one item of networking equipment 20 to adaptors or into the chassis 12.

Cable desired RJ-45/coax/copper/fiber optic ends (depending on the amount and type of ports used) to the at least one item of networking equipment 20, being certain to install a cable labeled 1 into a port 1, a cable 2 into a port 2, etc.;

Insert a power cable 18 into the at least one item of networking hardware equipment 20, and close any lid securely; and slide the drawer 10 or adapted hardware into an available slot on the rack 14 (or said at least one slot) or mail to a customer to slide into an available slot on or in a remote rack at a customer site.

In some embodiments, the present invention may comprise a fully equipped pre-cabled box or receiver chassis 12 containing adapted hardware 20 as described herein, further comprising pre-installed hardware 20 including pre-installed software, in an intelligent management system (Artificial intelligence), which may provide an Admin-in-a-Box™ system that is ready for installation and use, or ready for use as a standalone system.

In summary, in an exemplary embodiment, the present invention may provide a drawer-like container or slide in drawer like design for computer networking equipment 20 to be installed and pre-cabled 22a to a connector 22b to allow for quick installation and removal or replacement into a housing network rack 14, whereby failed or upgraded equipment may be swapped in seconds by almost anyone. The present invention may further comprise a kit comprising a standalone fully equipped pre-cabled computer hardware system and a computer software system for operating the computer hardware system.

The computer-based data processing system and method described above is for purposes of example only, and may be implemented in any type of computer system or programming or processing environment, or in a computer program, alone or in conjunction with hardware. The present invention may also be implemented in software stored on a computer-readable medium and executed as a computer program on a general purpose or special purpose computer. For clarity, only those aspects of the system germane to the invention are described, and product details well known in the art are omitted. For the same reason, the computer hardware is not described in further detail. It should thus be understood that the invention is not limited to any specific computer language, program, or computer. It is further contemplated that the present invention may be run on a stand-alone computer system, or may be run from a server computer system that can be accessed by a plurality of client computer systems interconnected over an intranet network, or that is accessible to clients over the Internet. In addition, many embodiments of the present invention have application to a wide range of industries. To the extent the present application discloses a system, the method implemented by that system, as well as software stored on a computer-readable medium and executed as a computer program to perform the method on a general purpose or special purpose computer, are within the scope of the present invention. Further, to the extent the present application discloses a method, a system of apparatuses configured to implement the method are within the scope of the present invention.

It should be understood, of course, that the foregoing relates to exemplary embodiments of the invention and that modifications may be made without departing from the spirit and scope of the invention as set forth in the following claims.

What is claimed is:

1. A pre-cabled drawer system for operatively connecting a hardware component with a computing infrastructure, comprising:
a removable chassis configured as a tray to contain the hardware component, a first connector mounted to an aft wall of the removable chassis, a first wiring operatively connecting the hardware component with the first connector; and
a rack configured to receive the removable chassis therein, a second connector attached with an aft end of the rack, a second wiring operatively connecting the second connector with the computing infrastructure, wherein the first connector and the second connector are cooperatively connected when the removable chassis is received within the rack.

2. The pre-cabled drawer system of claim 1, further comprising:
a slide element disposed between a sidewall of the removable chassis and the rack to movably carry the chassis in the rack.

3. The pre-cabled drawer system of claim 1, wherein the first connector and the second connector have a unique conductor configuration associated with a specified hardware package within the computing infrastructure.

4. The pre-cabled drawer system of claim 1, wherein the first connector and the second connector have a unique cooperative body connection associated with a specified hardware package within the computing infrastructure.

5. The pre-cabled drawer system of claim 1, wherein the first connector and the second connector have a unique position on each of the respective chassis and the rack, such that a specifically configured chassis may only be received for interconnection with the computing infrastructure at a specified location within the rack.

6. The pre-cabled drawer system of claim 1, further comprising:
a plurality of first connectors disposed in a spaced apart relation about the aft wall of the removable chassis;
a plurality of first wires to interconnect the hardware component with the plurality of first connectors; and
a plurality of second connectors attached with the aft end of the rack, the plurality of second connectors disposed in a corresponding spaced apart relation with the plurality of first connectors.

7. The pre-cabled drawer system of claim 1, wherein a second removable chassis is configured to contain a second hardware component as a modular replacement for the hardware component of the removable chassis.

8. A chassis for operatively connecting a hardware component with a computing infrastructure, comprising:
a removable chassis configured as a tray to contain the hardware component;
a first wiring operatively connecting the hardware component with a first connector; and
the first connector mounted to an aft wall of the chassis, the first connector configured for operative connection with a second connector of a rack to receive the removable chassis therein for connection with the computing infrastructure.

9. The chassis of claim 8, further comprising:
a power supply contained within the removable chassis; and
a power conductor operatively connected with the hardware component.

10. The chassis of claim 9, further comprising:
a plurality of first connectors disposed in a spaced apart relation about the aft wall of the chassis;
a plurality of first wires to interconnect the hardware component with the plurality of first connectors; and
the plurality of first connectors configured for operative connection with a plurality of second connectors attached with an aft end of the rack disposed in a corresponding spaced apart relation with the plurality of first connectors.
